(19) United States
(12) Patent Application Publication
(10) Pub. No.: US 2019/0081003 A1
(43) Pub. Date: Mar. 14, 2019

(54) SEMICONDUCTOR PACKAGE AND METHOD OF MANUFACTURING THE SAME

(71) Applicant: TOSHIBA MEMORY CORPORATION, Tokyo (JP)

(72) Inventor: Yorichika BANDO, Fujisawa Kanagawa (JP)

(73) Assignee: TOSHIBA MEMORY CORPORATION, Tokyo (JP)

(21) Appl. No.: 15/905,288

(22) Filed: Feb. 26, 2018

(30) Foreign Application Priority Data
Sep. 13, 2017 (JP) 2017-176057

(51) Int. Cl. H01L 23/532; H01L 23/498; H01L 23/522; H01L 23/29; H01L 23/00

(52) U.S. Cl. CPC H01L 23/53228; H01L 23/49816; H01L 24/03; H01L 23/293; H01L 23/5228

(57) ABSTRACT

A semiconductor package is described. The semiconductor package includes a substrate, a line trace, a solder resist and an organic film. The line trace contains copper. The solder resist is disposed on the line trace. The line trace has end surfaces that are spaced apart from each other on the substrate. The solder resist has an opening between the end surfaces. The organic film covers the end surfaces.

### CROSS-REFERENCE TO RELATED APPLICATION

This application claims the benefit of and priority to Japanese Patent Application No. 2017-176057, filed Sep. 13, 2017, the entire contents of which are incorporated herein by reference.

### FIELD

An embodiment described herein relates to a semiconductor package and a method of manufacturing the same.

### BACKGROUND

In a manufacturing process of a semiconductor package, electroplating treatment may be performed by energizing a line trace provided on a substrate. At this time, if line trace density is high, the line trace may be energized in a state where the line trace is short-circuited, and the line trace may be separated, such as during patterning, after the electroplating treatment. The line trace is separated, for example, by performing etching using a solder resist provided on the line trace as a mask.

### DESCRIPTION OF THE DRAWINGS

FIGS. 1A and 1C are plan views of a semiconductor package according to an embodiment, and FIGS. 1B and 1D are cross-sectional views taken along a cutting line X-X and a cutting line Y-Y, respectively;

FIG. 2 is a flowchart showing a manufacturing process of the semiconductor package according to the embodiment;

FIGS. 3A and 3C are plan views for explaining a solder resist forming process, and FIGS. 3B and 3D are cross-sectional views taken along a cutting line X-X and a cutting line Y-Y, respectively;

FIGS. 4A and 4C are plan views for explaining an opening forming process, and FIGS. 4B and 4D are cross-sectional views taken along a cutting line X-X and a cutting line Y-Y, respectively;

FIGS. 5A and 5C are plan views for explaining an opening forming process, and FIGS. 5B and 5D are cross-sectional views taken along a cutting line X-X and a cutting line Y-Y, respectively;

FIGS. 6A and 6C are plan views for explaining a resist coating process, and FIGS. 6B and 6D are cross-sectional views taken along a cutting line X-X and a cutting line Y-Y, respectively;

FIGS. 7A and 7C are plan views for explaining a line trace separation process, and FIGS. 7B and 7D are cross-sectional views taken along a cutting line X-X and a cutting line Y-Y, respectively; and

FIGS. 8A and 8C are plan views for explaining a semiconductor package after an organic film forming process, and FIGS. 8B and 8D are cross-sectional views taken along a cutting line X-X and a cutting line Y-Y, respectively.

### DETAILED DESCRIPTION

When a line trace is separated as described above, an end surface of the separated line trace is exposed. Shipment in a state that the end surface is exposed may cause a problem such as line trace short-circuiting due to dust or the like.

Exemplary embodiments provide a semiconductor package with improved reliability and a method of manufacturing the package.

According to some embodiments, a semiconductor package comprises a substrate, a line trace containing copper, a solder resist provided on the line trace, and an organic film. The line trace has end surfaces that are spaced apart from each other on the substrate. The solder resist has an opening between the end surfaces. The organic film covers the end surfaces.

Embodiments of the present disclosure will be described below with reference to the accompanying drawings. The embodiments do not limit the present disclosure.

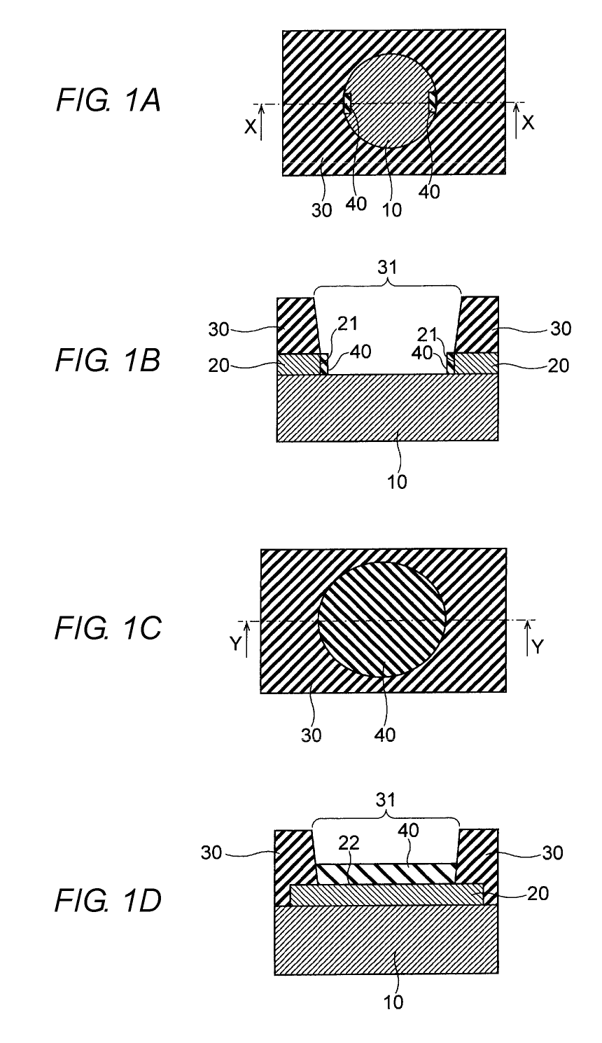

FIG. 1A is a plan view showing a line trace separation region of a semiconductor package according to some embodiments, and FIG. 1B is a cross-sectional view taken along a cutting line X-X shown in FIG. 1A. Further, FIG. 1C is a plan view showing a land region of the semiconductor package according to some embodiments, and FIG. 1D is a cross-sectional view taken along a cutting line Y-Y shown in FIG. 1C.

The semiconductor package according to some embodiments is a BGA (Ball Grid Array) type package. The semiconductor package comprises a substrate 10, a plurality of line traces 20, a solder resist 30 and an organic film 40.

For example, a glass epoxy substrate may be applied as the substrate 10. The plurality of line traces 20 are provided on the substrate 10.

Each of the line traces 20 may be a copper wire. The line trace 20 has two end surfaces 21 (see FIG. 1B) opposed to each other in the line trace separation region. The line trace 20 also has a bonding surface 22 (see FIG. 1D) to be bonded to a solder ball for mounting (not shown in FIGS. 1A-1D).

The solder resist 30 may be an insulating film covering the surface of the line trace 20. The solder resist 30 functions as a protective film for preventing adhesion of a solder. The solder resist 30 has an opening 31 above the bonding surface 22 and between the end surfaces 21. In other words, the opening 31 is provided in the land region and the separation region of the line trace 20.

The organic film 40 covers the end surfaces 21 and the bonding surface 22, thereby preventing oxidation of copper contained in the line trace 20. The organic film 40 may contain, for example, a chemical complex of copper and an imidazole compound.

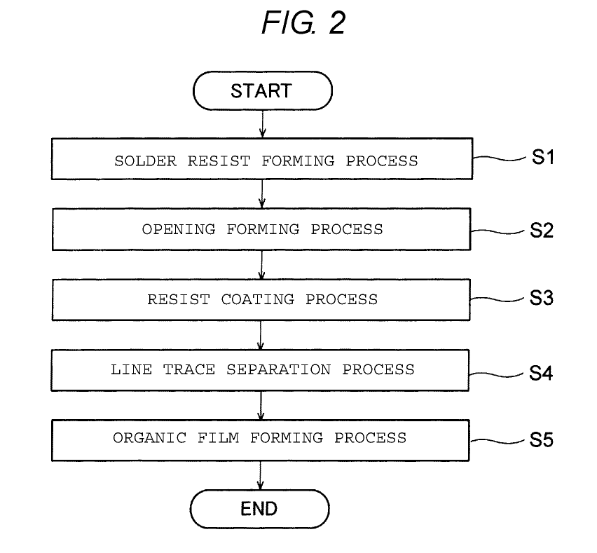

Hereinafter, a method of manufacturing a semiconductor package according to some embodiments will be described. FIG. 2 is a flowchart showing a manufacturing process of the semiconductor package according to some embodiments. As shown in FIG. 2, in the embodiment, a solder resist forming process (step S1), an opening forming process (step S2), a resist coating process (step S3), a line trace separation process (step S4) and an organic film forming process (step S5) are sequentially executed. Each process is described below.

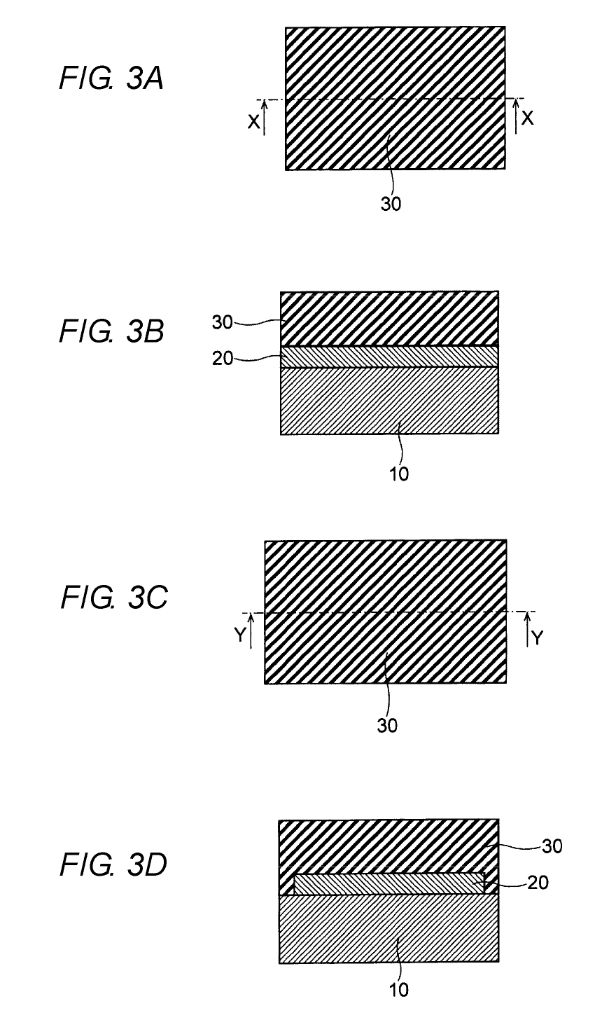

First, the solder resist forming process (step S1) is described with reference to FIGS. 3A to 3D. FIGS. 3A to 3D are plan views and cross-sectional views corresponding to FIGS. 1A to 1D, respectively.

As shown in FIGS. 3A to 3D, in the solder resist forming process, the plurality of line traces 20 are coated with the solder resist 30. As a result, the surface of each of the line traces 20 is covered with the solder resist 30.

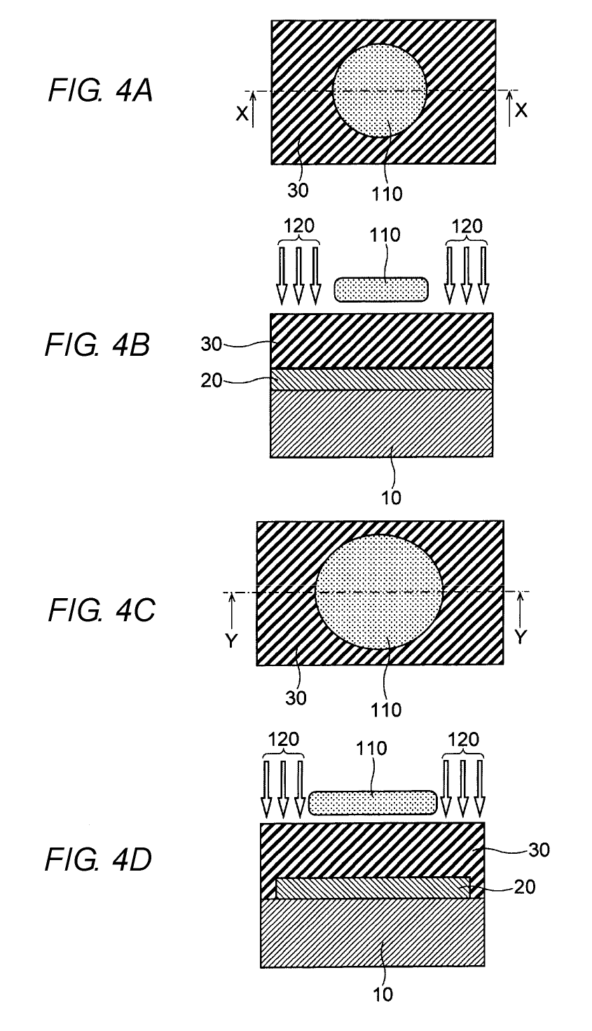

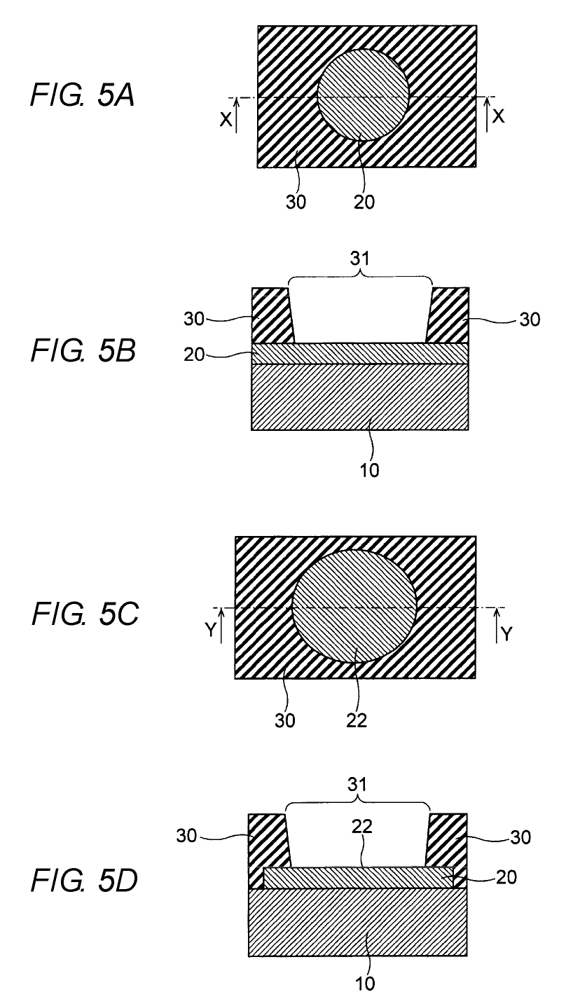

Next, the opening forming process (step S2) is described with reference to FIGS. 4A to 4D and FIGS. 5A to 5D. These FIGS. are also plan views and cross-sectional views corresponding to FIGS. 1A to 1D, respectively.

In the opening forming process, first, as shown in FIGS. 4A and 4D, a pattern of the opening 31 is formed in the line trace separation region and the land region by a mask 110 and exposure 120. Next, as shown in FIGS. 5A to 5D, the opening 31 is formed in the line trace separation region and the land region by a development process.

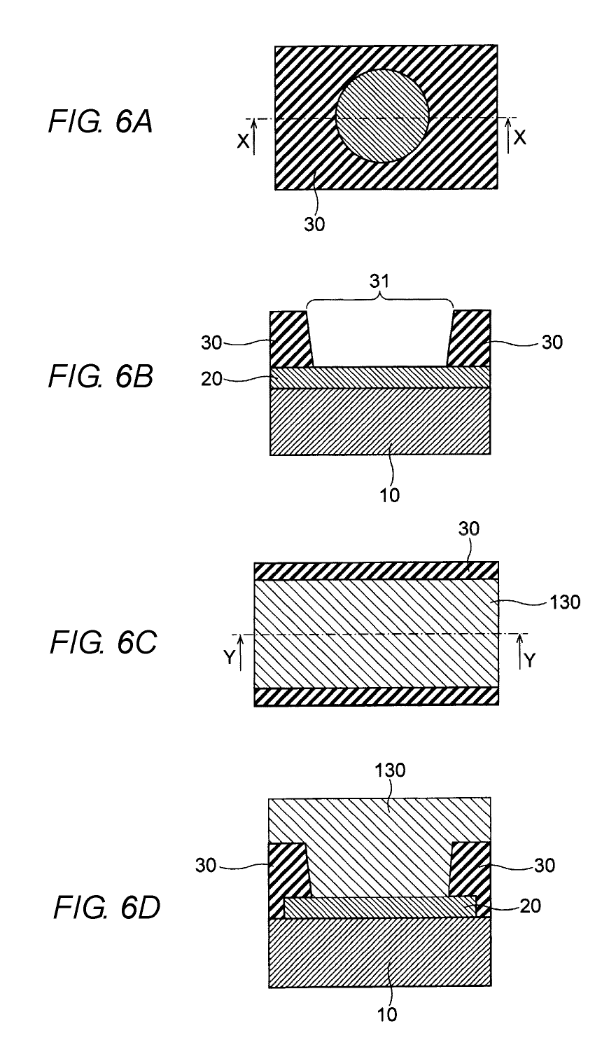

Next, the resist coating process (step S3) is described with reference to FIGS. 6A to 6D. FIGS. 6A to 6D are also plan views and cross-sectional views corresponding to FIGS. 1A to 1D, respectively.

In the resist coating process, as shown in FIGS. 6A to 6D, only the opening 31 formed in the land region is coated with a resist 130. As a result, the opening 31 is blocked by the resist 130. The resist 130 is a different type of protective film than the solder resist 30 and functions as a mask for protecting the bonding surface 22 of the line trace 20 in a line trace separation process described later.

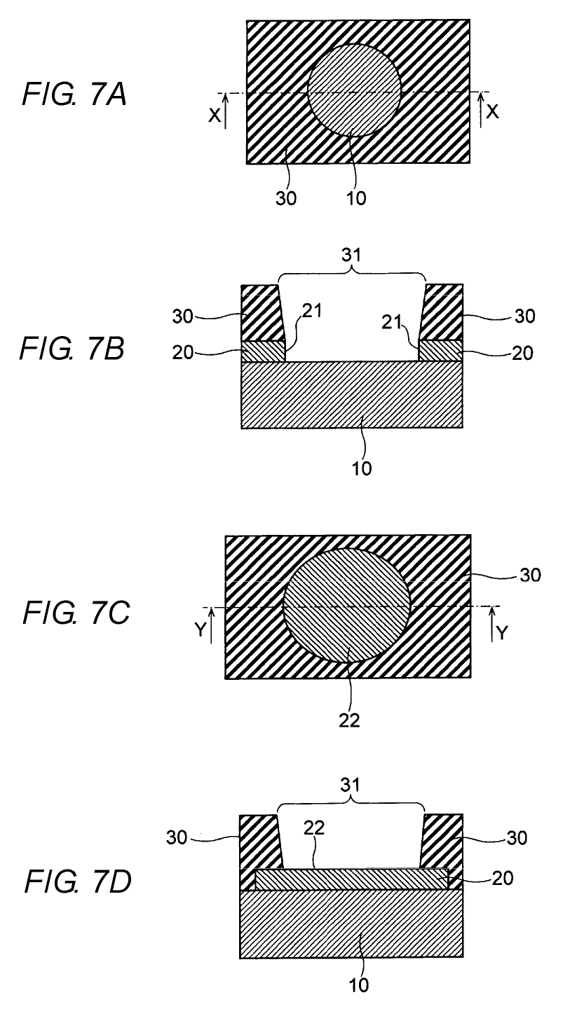

Next, the line trace separation process (step S4) is described with reference to FIGS. 7A to 7D. FIGS. 7A to 7D are also plan views and cross-sectional views corresponding to FIGS. 1A to 1D, respectively.

In the line trace separation process, the line trace 20 exposed from the opening 31 may be wet-etched. As a result, the line trace 20 is separated as shown in FIGS. 7A and 7B. At this time, in order to form the organic film 40 by electroless plating treatment in an organic film forming process described later, the line trace 20 is etched in such a manner that the end surfaces 21 of the line trace 20 are not recessed with respect to the solder resist 30, and thus over-etching does not occur. After separation of the line traces 20, the resist 130 is peeled off as shown in FIGS. 7C and 7D.

Next, the organic film forming process (step S5) is described. In the organic film forming process, the organic film 40 is formed on the end surfaces 21 and the bonding surface 22 of the line trace 20 at the same time by electroless plating treatment. Specifically, the semiconductor package after the line trace separation process is immersed in a treatment liquid containing, for example, an imidazole compound as a main component for a predetermined time. In the treatment liquid, a chemical reaction of copper and the imidazole compound occurs at the end surfaces 21 and the bonding surface 22. As a result, as shown in FIGS. 1A to 1D, the organic film 40 is formed on the end surfaces 21 and the bonding surface 22 at the same time. At this time, the organic film 40 formed on each of the end surfaces 21 is exposed from the opening 31.

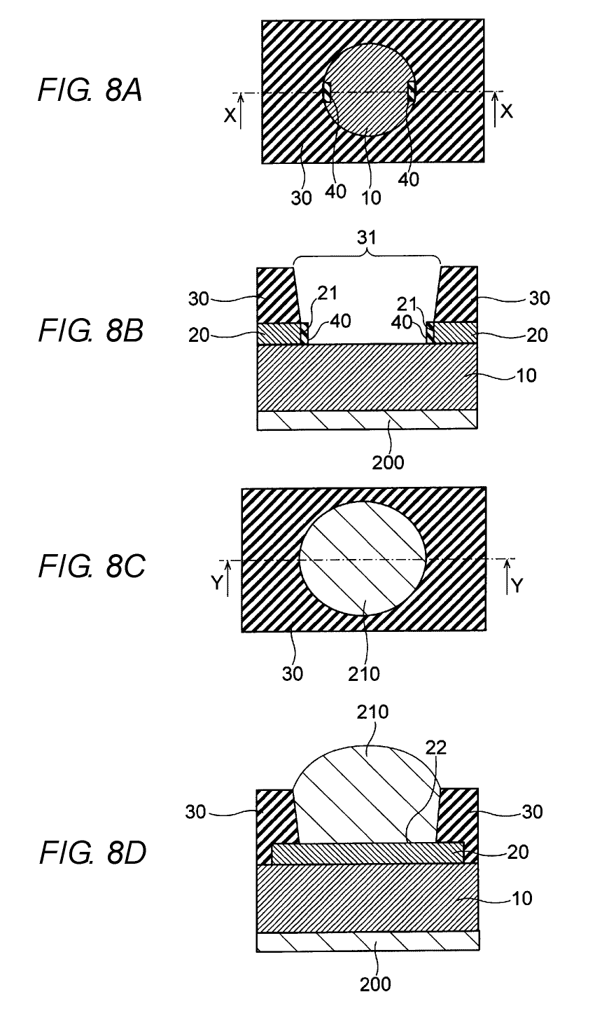

In the semiconductor package having the organic film 40 formed thereon, as shown in FIGS. 8A to 8D, a semiconductor element 200 is implemented under the substrate 10, specfically on a surface opposite to the surface on which the line trace 20 is provided (see FIGS. 8B and 8D). As a result, the line trace 20 may function as a signal line for transmitting a signal input/output to/from the semiconductor element 200. When the semiconductor element 200 is, for example, a semiconductor memory, a signal transmitted through the line trace 20 may include data to be written in the semiconductor memory, data read from the semiconductor memory, a command for driving the semiconductor memory and the like.

Further, a solder ball 210 is bonded to the bonding surface 22 of the line trace 20 (see FIGS. 8C and 8D). At this time, the organic film 40 formed on the bonding surface 22 is absorbed in the solder ball 210 and disappears.

According to some embodiments described above, each of the end surfaces 21 exposed by the separation of the line trace 20 is covered with the organic film 40. Therefore, it is possible to prevent foreign matter such as dust from adhering to the end surface 21. This avoids troubles such as line trace short-circuiting. Therefore, the reliability can be improved.

Further, in some embodiments, the line trace 20 is separated so as not to cause overetching. Therefore, the organic film 40 is formed on each of the end surfaces 21 at the same time as the formation of the organic film on the bonding surface 22 by the electroless plating treatment carried out in the related art. As a result, no extra process is required. Therefore, the reliability can be improved without lowering the manufacturing efficiency.

In some embodiments, since the line trace separation region is provided in the middle of the line trace 20 formed in a straight line, the end surfaces 20 are opposed to each other in the line trace separation region. However, the positional relationship of the end surfaces 20 is not limited to an arrangement in which they are opposed to each other as long as the end surfaces 20 are spaced apart from each other in the line trace separation region. For example, when the line trace separation region is at an intersection of line traces 20 formed in L shape, T shape, Y shape or the like, the end surfaces 20 are spaced apart from each other in the line trace separation region.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor package, comprising:
a substrate;
a line trace, comprising copper, having end surfaces spaced apart from each other on the substrate;
a solder resist provided on the line trace, and having an opening between the end surfaces; and
an organic film covering the end surfaces.

2. The semiconductor package according to claim 1, wherein the organic film is exposed through the opening.

3. The semiconductor package according to claim 1, wherein the organic film comprises a complex of copper and an imidazole compound.

4. The semiconductor package according to claim 1, further comprising
a semiconductor element disposed under the substrate, and
wherein the line trace comprises a signal line arranged to transmit a signal input/output to/from the semiconductor element.

5. The semiconductor package according to claim 4, wherein the semiconductor element comprises a semiconductor memory.

6. The semiconductor package according to claim 1, wherein the line trace further includes a land region, the organic film disposed on a top surface of the line trace in the land region.

7. The semiconductor package according to claim 1, wherein the organic film and the solder resist comprise a different material.

8. The semiconductor package according to claim 1, wherein the organic film covers all surfaces of the line trace exposed through openings in the organic film.

9. A method of manufacturing a semiconductor package, comprising:
forming a solder resist on a line trace, comprising copper, disposed on a substrate;
forming an opening in the solder resist;
etching the line trace exposed from the opening using the solder resist as a mask to form end surfaces of the line trace exposed in the opening; and
forming an organic film on the end surfaces of the line trace exposed in the opening.

10. The method of manufacturing a semiconductor package according to claim 9, further comprising:
forming a plurality of the openings in the solder resist,
coating a part of the openings with a second resist comprising a different material than that of the solder resist;
etching the line trace using the second resist as the mask, and peeling off the second resist; and
forming the organic film on the surface of the line trace exposed through the openings and the end surfaces at the same time.

11. The method of manufacturing a semiconductor package according to claim 9, wherein the organic film is formed by an electroless plating treatment.

12. The method of manufacturing a semiconductor package according to claim 11, wherein the electroless plating treatment comprises exposing the semiconductor package to an imidazole compound.

13. The method of manufacturing a semiconductor package according to claim 10, wherein the organic film is formed by an electroless plating treatment.

14. The method of manufacturing a semiconductor package according to claim 9,further comprising forming solder balls on land regions of the line trace.

15. The method of manufacturing a semiconductor package according to claim 9, wherein the forming the organic film forms the organic film on all exposed surfaces of the line trace.

16. The method of manufacturing a semiconductor package according to claim 9,further comprising:
forming a semiconductor element under the substrate, wherein the line trace comprises a signal line arranged to transmit a signal input/output to/from the semiconductor element
